(19) United States
(12) Patent Application Publication
(10) Pub. No.: US 2009/0212361 A1
(43) Pub. Date: Aug. 27, 2009

(54) Semiconductor device and method of manufacturing the same

(76) Inventor: Yuichiro Kitajima, Chiba-shi (JP)

Correspondence Address: BRUCE L. ADAMS, ESQ, ADAMS & WILKS, 17 BATTERY PLACE-SUITE 1231, NEW YORK, NY, 10004, US

(21) Appl. No.: 12/380,373

(22) Filed: Feb. 26, 2009

(30) Foreign Application Priority Data
Feb. 27, 2008 (JP) 2008-046371
Jan. 29, 2009 (JP) 2009-018250

(51) Int. Cl. H01L 29/78; H01L 21/336

(52) U.S. Cl. 257/343; 438/286; 257/E29.256; 257/E21.417

(57) ABSTRACT

A LOCOS offset type MOS transistor includes a MOS transistor including: a gate electrode formed on a gate oxide film, the gate oxide film being formed on a surface of a semiconductor substrate of a first conductivity type; a LOCOS oxide film and a first offset diffusion layer of a second conductivity type, which are formed on the surface of the semiconductor substrate at one of both sides and only one side of the gate electrode, a part of a region of the LOCOS oxide film, which is not an end of the LOCOS oxide film, being removed; and one of both of a source diffusion layer and a drain diffusion layer of the second conductivity type and only a drain diffusion layer of the second conductivity type is formed in the first offset diffusion layer corresponding to the region in which the LOCOS oxide film is removed. Accordingly, a semiconductor device may be provided including the MOS transistor which has a high break down voltage and ensures a proper operation even at a voltage of 50 V or higher by covering a region in which electric field accumulation is caused below the drain diffusion layer with the offset diffusion layer.

### BACKGROUND OF THE INVENTION

1. Field of the Invention

The present invention relates to a semiconductor device including a LOCOS offset type field-effect transistor with high breakdown voltage and a method of manufacturing the same.

2. Description of the Related Art

At present, there are various demands from the market on ICs for controlling power supply voltage to give an output of a predetermined level of voltage, such as a voltage regulator and a switching regulator. For example, there arises a demand for the ICs which ensure the proper operation even in a voltage range of 50 V or higher. Field-effect transistors (hereinafter, referred to as MOS transistors) used in the ICs with high breakdown voltage include a MOS transistor having a LOCOS offset drain structure (hereinafter, referred to as a LOCOS offset MOS transistor), which is a conventional planar MOS transistor with high breakdown voltage.

FIG. 5 illustrates a method of manufacturing a LOCOS offset MOS transistor. As illustrated in FIG. 5A, a sacrificial oxide film 22 and a nitride film 21 are deposited on a p-type silicon substrate, the nitride film 21 is selectively removed with a photoresist patterned so as to provide an opening in a desired region as a mask, and an n-type offset diffusion layer 31 is formed by ion implantation. Then, as illustrated in FIG. 5B, a LOCOS oxide film 23 is selectively grown and formed by, for example, wet oxidation with the nitride film 21 being used as a patterned mask. Then, the nitride film 21 and the sacrificial oxide film 22 are removed, a gate oxide film 24 is formed, and, for example, a polycrystalline silicon film is deposited on the gate oxide film 24. Then, by removing the polycrystalline silicon film with a photoresist patterned so as to provide an opening in a desired region as a mask, a gate electrode 25 is formed. Then, by ion implantation with a photoresist patterned so as to provide an opening in a desired region as a mask, an n-type drain diffusion layer 34 and an n-type source diffusion layer 35 are formed to obtain a structure illustrated in FIG. 5C.

In the conventional structure illustrated in FIG. 5C, it is understood that, with regard to electric field relaxation between the gate electrode and a drain electrode, the breakdown voltage may be sufficiently high by making optimum the thickness of the LOCOS oxide film 23 and the concentration of the offset diffusion layer 31. However, with regard to a connection between the offset diffusion layer 31 and the drain diffusion layer 34, variations in the thickness of the LOCOS oxide film 23 and in the thickness of the nitride film 21 occur in a manufacturing process. The degree of the connection varies with change of the shape of a bird's beak at an end of the LOCOS oxide film 23. In this way, having a factor for the unstable connection, the structure is insufficient for relaxation of electric field accumulation in a region below the drain diffusion layer 34. For example, making the impurity concentration of the offset diffusion layer 31 sufficiently high for a stable connection between the drain diffusion layer 34 and the offset diffusion layer 31 strengthens the electric field since extension of the depletion layer of the offset diffusion layer 31 is inhibited, causing avalanche breakdown at a relatively low voltage. It is difficult to apply the above-mentioned structure in a device design for an element having a high breakdown voltage as high as 50V.

As a measure against the above-mentioned problem, a trench is formed in an offset portion of a LOCOS offset MOS transistor to form an offset diffusion layer, and a LOCOS oxide film is embedded therein, thereby covering an electric field accumulation region of a heavily doped drain layer by the offset diffusion (see, for example, Japanese Patent Application Laid-open No. JP 6-29313).

In the structure of the MOS transistor disclosed in the Japanese Patent Application, the large effective width of the offset diffusion layer makes the resistance component larger, reducing the driving ability of the MOS transistor. Further, the shape of a recessed portion, in which the LOCOS oxide film is embedded, tapers in an upward direction, whereby the offset diffusion layer also tapers in the upward direction, and thus, the diffusion layer extends also in a channel direction of the MOS transistor. Accordingly the gate length of the MOS transistor is needed to be large in order to prevent leak current due to a punch-through phenomenon caused by a contact between depletion layers one formed between the drain offset diffusion layer and the substrate, and another depletion layer on the side of the source diffusion layer when a high voltage is applied to the drain electrode. In particular, the gate length becomes significantly large in a case of a structure in which a high breakdown voltage is required for both the drain electrode and the source electrode, and thus, the increased size significantly affects the manufacturing cost.

Above all, due to manufacturing variations in forming the recessed portion in the offset region and in forming the LOCOS oxide film embedded in the recessed portion, the breakdown voltage between the gate electrode and the drain electrode fluctuates. For example, when the recessed portion becomes deeper and the LOCOS oxide film is grown thin due to the manufacturing variations, a channel end portion of the offset diffusion layer has a sharp edge to which electric field accumulates, and the breakdown voltage is thus extremely lowered. Accordingly, taking the manufacturing variations and the like into consideration, it is understood that to ensure the proper operation with the above-mentioned structure at a high voltage is considerably difficult.

### SUMMARY OF THE INVENTION

In order to solve the above-mentioned problem, the present invention adopts the following measures.

(1) A semiconductor device includes a MOS transistor including:

a gate electrode formed on a gate oxide film, the gate oxide film being formed on a surface of a semiconductor substrate of a first conductivity type;

a LOCOS oxide film and a first offset diffusion layer of a second conductivity type, which are formed on the surface of the semiconductor substrate at one of both sides and only one side of the gate electrode, a part of a region of the LOCOS oxide film, which is not an end of the LOCOS oxide film, being removed; and

one of both of a source diffusion layer and a drain diffusion layer of the second conductivity type and only a drain diffusion layer of the second conductivity type is formed in the first offset diffusion layer corresponding to the region in which the LOCOS oxide film is removed.

(2) In the semiconductor device according to Item (1), the MOS transistor further includes a second offset diffusion layer of the second conductivity type on a periphery of one of both of the source diffusion layer and the drain diffusion layer and only the drain diffusion layer.

(3) A method of manufacturing a semiconductor device includes:

forming a sacrificial oxide film on a semiconductor substrate of a first conductivity type;

forming a nitride film on the sacrificial oxide film;

etching the nitride film only in a desired region using a patterned photoresist;

forming by ion implantation an offset diffusion layer of a second conductivity type only in a region to be a first offset diffusion layer;

forming a LOCOS oxide film in the region in which the nitride film is etched;

removing the nitride film and the sacrificial oxide film;

forming a gate oxide film on a surface of the semiconductor substrate, forming a polycrystalline silicon film, and etching the polycrystalline silicon film only in a desired region using a patterned photoresist;

etching the LOCOS oxide film in a region of the LOCOS oxide film, in which one of both of a source diffusion layer and a drain diffusion layer and only a drain diffusion layer is to be formed, using a patterned photoresist; and

forming by ion implantation a source diffusion layer of the second conductivity type and a drain diffusion layer of the second conductivity type in one of only the region in which the LOCOS oxide film is removed and both the region in which the LOCOS oxide film is removed and the region in which the source diffusion layer is to be formed.

(4) A method of manufacturing a semiconductor device includes:

forming a sacrificial oxide film on a semiconductor substrate of a first conductivity type;

forming a nitride film on the sacrificial oxide film;

etching the nitride film only in a desired region using a patterned photoresist;

forming by ion implantation a first offset diffusion layer of a second conductivity type only in a region to be the first offset diffusion layer;

forming by ion implantation a second offset diffusion layer of the second conductivity type only in a region to be the second offset diffusion layer;

forming a LOCOS oxide film in the region in which the nitride film is etched;

removing the nitride film and the sacrificial oxide film;

forming a gate oxide film on a surface of the semiconductor substrate, forming a polycrystalline silicon film, and etching the polycrystalline silicon film only in a desired region using a patterned photoresist;

etching the LOCOS oxide film in a region of the LOCOS oxide film, in which one of both of a source diffusion layer and a drain diffusion layer and only a drain diffusion layer is to be formed, using a patterned photoresist; and

forming by ion implantation a source diffusion layer of the second conductivity type and a drain diffusion layer of the second conductivity type in one of only the region in which the LOCOS oxide film is removed and both the region in which the LOCOS oxide film is removed and the region in which the source diffusion layer is to be formed.

Formation of both the source diffusion layer and the drain diffusion layer or only the drain diffusion layer of the LOCOS offset MOS transistor in the region in which a part of the LOCOS oxide film is etched can provide a semiconductor device including a MOS transistor which ensures the proper operation thereof even at a voltage of 50 V or higher by covering a region in which electric field accumulation is caused below both the source diffusion layer and the drain diffusion layer or only below the drain diffusion layer with the offset diffusion layer under the LOCOS oxide film.

### BRIEF DESCRIPTION OF THE DRAWINGS

In the accompanying drawings:

FIGS. 1A to 1D are schematic sectional views illustrating a flow of a method of manufacturing a semiconductor device according to a first embodiment of the present invention;

FIG. 2 is a schematic sectional view illustrating the semiconductor device according to the first embodiment of the present invention;

FIGS. 3A to 3D are schematic sectional views illustrating a flow of a method of manufacturing a semiconductor device according to a second embodiment of the present invention;

FIG. 4 is a schematic sectional view illustrating the semiconductor device according to the second embodiment of the present invention; and

FIGS. 5A to 5C are schematic sectional views illustrating a flow of a conventional method of manufacturing a semiconductor device.

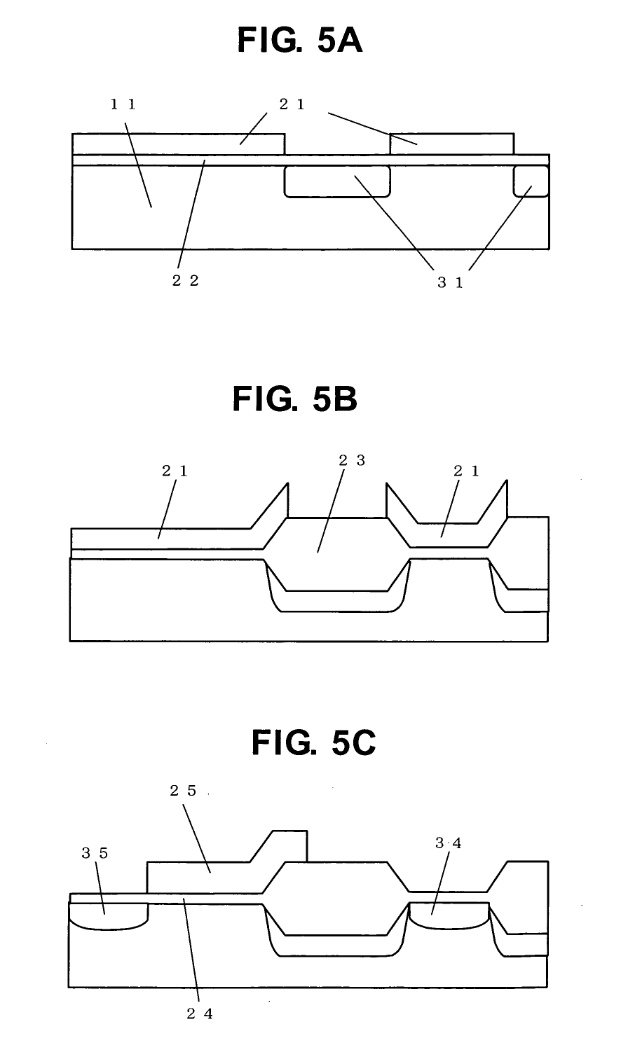

### DETAILED DESCRIPTION OF THE INVENTION

Embodiments of the present invention are described in detail in the following with reference to the attached drawings.

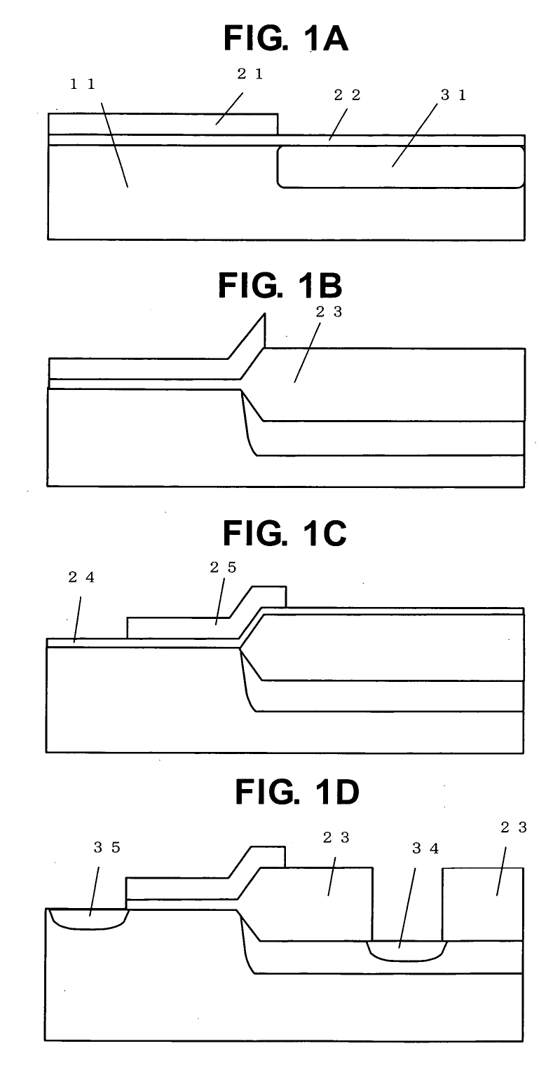

FIGS. 1A to 1D illustrate a method of manufacturing a semiconductor device according to a first embodiment of the present invention. In the following description, a case of an n-channel MOS transistor is described as an example.

A sacrificial oxide film 22 is formed on a p-type semiconductor substrate 11, and a nitride film 21 is formed on the sacrificial oxide film 22. After the nitride film 21 is patterned such that an opening is provided in a desired region, an offset diffusion layer 31 is formed by ion implantation in a surface region of the p-type semiconductor substrate 11 having the opening provided therein. Such a state is illustrated in FIG. 1A. The nitride film 21 is patterned by uniformly applying a photoresist onto the nitride film 21, providing the opening in the desired region of the photoresist by photolithography, and carrying out dry etching with the patterned photoresist being used as a mask with the use of, for example, a fluorine-based gas. When the offset diffusion layer 31 is formed by ion implantation, the mask used in etching the nitride film 21 is used as a mask and the final impurity concentration of the offset diffusion layer 31 is set in a range between about 1×10¹⁶ atom/cm³ to 1×10¹⁸ atom/cm³. Phosphorus is used as the impurity to be introduced. The implantation energy is set such that, depending on the amount of the impurity to be introduced, the final diffusion distance of the offset diffusion layer 31 from the surface of the semiconductor substrate in a depth direction is 0.3 μm or larger.

Then, thermal oxidation is carried out with the nitride film 21 being used as a mask in, for example, a wet oxygen atmosphere to form a LOCOS oxide film 23 of about 600 nm to 800 nm illustrated in FIG. 1B. Then, the nitride film 21 and the sacrificial oxide film 22 are removed, and a gate oxide film 24 is formed by thermal oxidation in, for example, a wet oxygen atmosphere. Then, a polycrystalline silicon film having a thickness of 200 nm to 400 nm is formed on an entire surface of the gate oxide film 24 by, for example, chemical vapor deposition. Phosphorus, for example, is diffused by solid phase diffusion method in the polycrystalline silicon film such that the impurity concentration thereof is about 1×10²⁰ atom/cm³ to give conductivity thereto. Here, the impurity may be implanted into the polycrystalline silicon film not by solid layer diffusion method but by ion implantation. After that, the conductive polycrystalline silicon film is patterned, a gate electrode 25 is formed at a desired location, and a structure illustrated in FIG. 1C is obtained.

Then, using a photoresist patterned such that an opening is provided in a desired region, dry etching of the LOCOS oxide film 23 is carried out using, for example, a fluorine-based gas. Here, when there is apprehension that the surface of the semiconductor substrate which appears through etching may have a small width, the LOCOS oxide film 23 may be thick, and thus, the aspect ratio may become larger, two-step etching, in which first etching of the LOCOS oxide film 23 is isotropic wet etching and second etching thereof is anisotropic dry etching, may relax the large aspect ratio.

Then, by forming a drain diffusion layer 34 and a source diffusion layer 35 by ion implantation with a photoresist patterned so as to provide openings in desired regions such as a region to be the drain diffusion layer and a region to be the source diffusion layer, in each of which the LOCOS oxide film 23 is removed, being used as a mask, a structure illustrated in FIG. 1D is obtained. Here, in the ion implantation for forming the drain diffusion layer 34 and the source diffusion layer 35, arsenic is used as the impurity to be introduced, and the final impurity concentration of a surface of the drain diffusion layer 34 and a surface of the source diffusion layer 35 is set to be 1×10¹⁹ atom/cm³ or larger. Phosphorus can also be used as the impurity to be introduced. The implantation energy is set such that the diffusion distance of each of the drain diffusion layer 34 and the source diffusion layer 35 from the surface of the semiconductor substrate in the depth direction is about 0.2 μm.

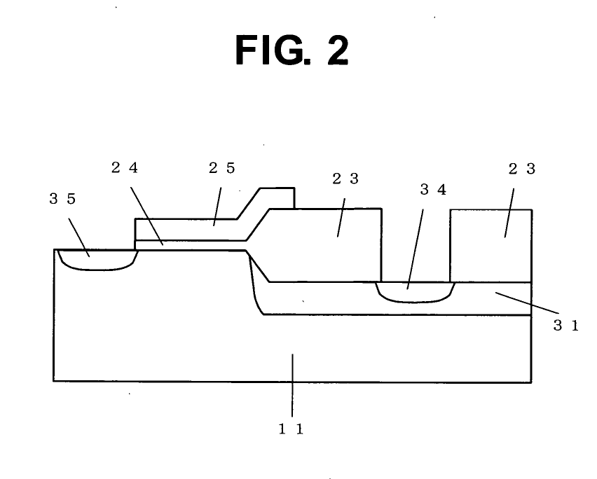

By forming, in this way, the drain diffusion layer 34 in the region in which a part of the LOCOS oxide film 23 of the LOCOS offset MOS transistor is etched as illustrated in FIG. 2, it is made possible to provide a semiconductor device including a MOS transistor which ensures the proper operation thereof even at a voltage of 50 V or higher by covering a region, in which electric field accumulation is caused below the drain diffusion layer 34, with the offset diffusion layer 31 below the LOCOS oxide film 23.

In the above, a case of an n-channel MOS transistor is described in detail, but it goes without saying that the present invention may also be applied to a case of a p-channel MOS transistor. When the MOS transistor is operated such that the source electrode and the drain electrode thereof are interchanged, the proper operation of both the source electrode and the drain electrode has to be ensured at a high voltage. Even in such a case, by applying the structure of the present invention to both the source diffusion layer and the drain diffusion layer, a high breakdown voltage may be ensured. Further, in the above, a case in which the MOS transistor is formed on a semiconductor substrate is described, but the present invention may also be applied to a case in which the MOS transistor is formed on a p-type deep diffusion layer, that is, a so-called well diffusion layer. Still further, the structure of the drain at a channel end is the same as that of a conventional LOCOS offset MOS transistor, and hence the characteristics of the MOS transistor are not inferior to those of the conventional MOS transistor.

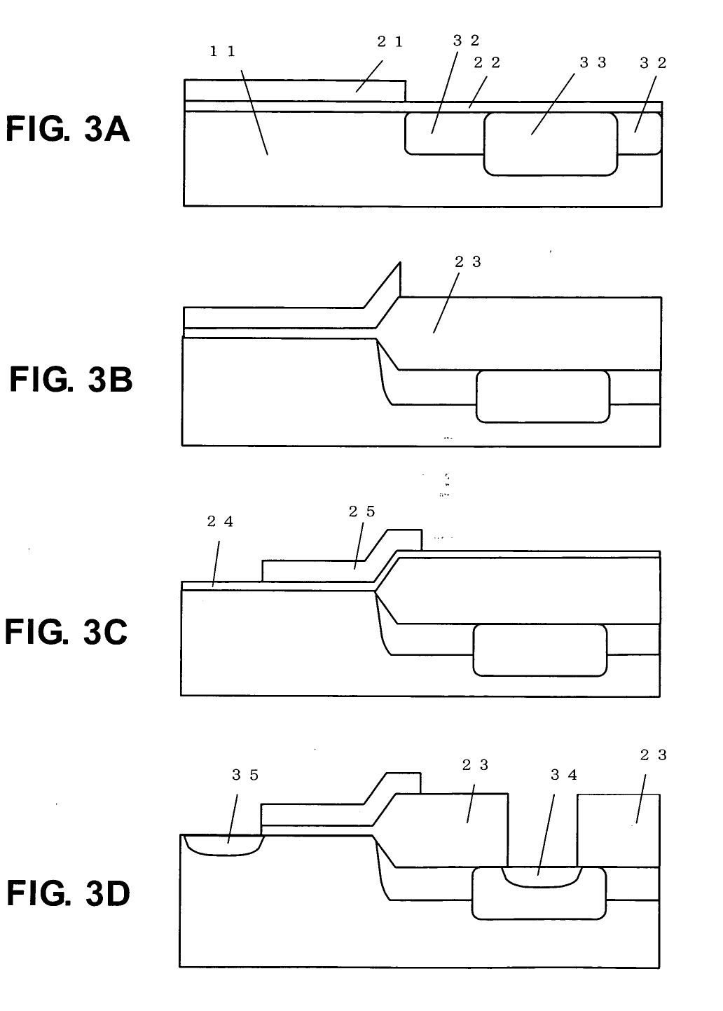

Next, FIGS. 3A to 3D illustrate a method of manufacturing a semiconductor device according to a second embodiment of the present invention. In the following description, a case of an n-channel MOS transistor is described as an example.

A sacrificial oxide film 22 is formed on a p-type semiconductor substrate 11, and a nitride film 21 is formed on the sacrificial oxide film 22. After the nitride film 21 is patterned such that an opening is provided in a desired region, a first offset diffusion layer 32 is formed by ion implantation in a surface region of the p-type semiconductor substrate 11 having the opening provided therein.

The nitride film 21 is patterned by uniformly applying a photoresist onto the nitride film 21, providing the opening in the desired region of the photoresist by photolithography, and carrying out dry etching with the patterned photoresist being used as a mask with the use of, for example, a fluorine-based gas. When the first offset diffusion layer 32 is formed by ion implantation, the mask used in etching the nitride film is used as a mask and the final impurity concentration of the first offset diffusion layer 32 is set in a range about 1×10¹⁶ atom/cm³ to 1×10¹⁸ atom/cm³. Phosphorus is used as the impurity to be introduced. The implantation energy is set such that, depending on the amount of the impurity to be introduced, the final diffusion distance of the first offset diffusion layer 32 from the surface of the semiconductor substrate in a depth direction is 0.3 μm or larger.

Then, a second offset diffusion layer 33 is formed in the first offset diffusion layer 32 by ion implantation with a photoresist patterned so as to provide an opening in a desired region being used as a mask, and a structure illustrated in FIG. 3A is obtained. When the second offset diffusion layer 33 is formed by ion implantation, the final impurity concentration of the second offset diffusion layer 33 is set in a range between about 1×10¹⁶ atom/cm³ to 1×10¹⁸ atom/cm³ and higher than that of the first offset diffusion layer 32. Phosphorus is used as the impurity to be introduced. The implantation energy is set such that the final diffusion distance of the second offset diffusion layer 33 from the surface of the semiconductor substrate in the depth direction is larger than the final diffusion distance of the first offset diffusion layer 32 from the surface of the semiconductor substrate in the depth direction. For example, when the implantation energy of the first offset diffusion layer 32 is 90 keV, the implantation energy of the second offset diffusion layer 33 is 180 keV. The second offset diffusion layer 33 is formed so as to cover a region in which a drain diffusion layer 34 is to be formed. Here, the width of the first offset diffusion layer 32 from a channel end to the second offset diffusion layer 33 is optimized in view of the breakdown voltage and electrical characteristics of the finally obtained MOS transistor, and the width of an overlap between the first offset diffusion layer 32 and the second offset diffusion layer 33 from an end of the drain diffusion layer 34 is optimized such that the electric field accumulation below the drain diffusion layer 34 is relaxed.

Then, thermal oxidation is carried out with the nitride film 21 being used as a mask in, for example, a wet oxygen atmosphere to form a LOCOS oxide film 23 of about 600 nm to 800 nm illustrated in FIG. 3B. Then, the nitride film 21 and the sacrificial oxide film 22 are removed, and a gate oxide film 24 is formed by thermal oxidation in, for example, a wet oxygen atmosphere. Then, a polycrystalline silicon film having a thickness of 200 nm to 400 nm is formed on an entire surface of the gate oxide film 24 by, for example, chemical vapor deposition. Phosphorus, for example, is diffused by solid layer diffusion method in the polycrystalline silicon film such that the impurity concentration thereof is about 1×10²⁰ atom/cm³ to give conductivity thereto. Here, the impurity may be implanted into the polycrystalline silicon film not by solid layer diffusion method but by ion implantation. After that, the conductive polycrystalline silicon film is patterned, a gate electrode 25 is formed at a desired location, and a structure illustrated in FIG. 3C is obtained.

Then, using a photoresist patterned such that an opening is provided in a desired region, dry etching of the LOCOS oxide film 23 is carried out using, for example, a fluorine-based gas. Here, when there is apprehension that the surface of the semiconductor substrate which appears through etching may have a small width, the LOCOS oxide film 23 may be thick, and thus, the aspect ratio may become larger, two-step etching, in which first etching of the LOCOS oxide film 23 is isotropic wet etching and second etching thereof is anisotropic dry etching, may relax the large aspect ratio thereof.

Then, by forming a drain diffusion layer 34 and a source diffusion layer 35 by ion implantation with a photoresist patterned so as to provide openings in desired regions such as a region to be the drain diffusion layer and a region to be the source diffusion layer, in each of which the LOCOS oxide film 23 is removed, being used as a mask, a structure illustrated in FIG. 3D is obtained. Here, in the ion implantation for forming the drain diffusion layer 34 and the source diffusion layer 35, arsenic is used as the impurity to be introduced, and the final impurity concentration of a surface of the drain diffusion layer 34 and a surface of the source diffusion layer 35 is set to be 1×10¹⁹ atom/cm³ or larger. Phosphorus can also be used as the impurity to be introduced. The implantation energy is set such that the diffusion distance of each of the drain diffusion layer 34 and the source diffusion layer 35 from the surface of the semiconductor substrate in the depth direction is about 0.2 μm.

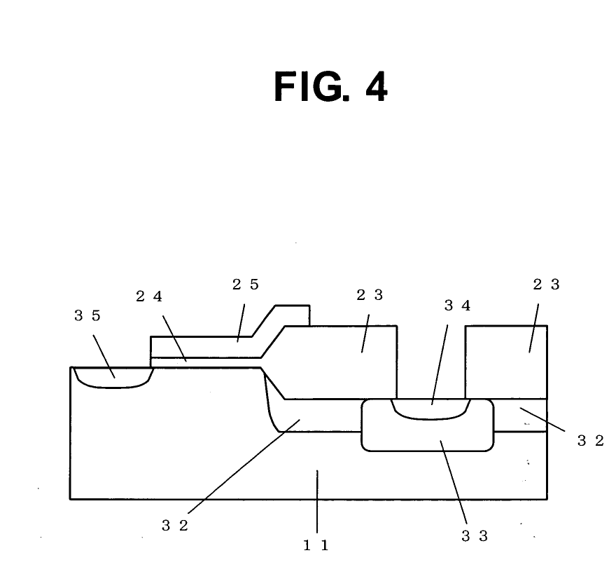

By forming, in this way, the drain diffusion layer 34 in the region in which a part of the LOCOS oxide film 23 of the LOCOS offset MOS transistor is etched as illustrated in FIG. 4, it is made possible to provide a semiconductor device including a MOS transistor which ensures the proper operation thereof even at a voltage of 50 V or higher by covering a region, in which electric field accumulation is caused below the drain diffusion layer 34, with the first offset diffusion layer 32 and the second offset diffusion layer 33.

In the LOCOS offset MOS transistor structure illustrated in FIG. 2 according to the first embodiment of the present invention, only the offset diffusion layer 31 is adapted to relax the electric field accumulation between the gate electrode 25 and the offset diffusion layer 31 and the electric field accumulation between the offset diffusion layer 31 and below the drain diffusion layer 34. In order to relax the former electric field accumulation, it is necessary to make the impurity concentration low in the offset diffusion layer 31, while, in order to relax the latter electric field accumulation, it is necessary to make the impurity concentration high in the offset diffusion layer 31, and thus, the two requirements are in a trade-off relationship. There are cases in which it is difficult for the structure illustrated in FIG. 2 to satisfy both the requirements. In particular, when the MOS transistor is used as an analog device, it is necessary to suppress impact ionization phenomenon caused between the channel and the offset diffusion layer, and at the same time, to suppress the electric field accumulation below the drain diffusion layer to secure a certain level of the drain breakdown voltage, and hence the above-mentioned problem becomes more conspicuous.

In view of this problem, as illustrated in FIG. 4, in the LOCOS offset MOS transistor structure according to the second embodiment of the present invention, the offset diffusion layer is a dual diffusion layer including the first offset diffusion layer 32 and the second offset diffusion layer 33, whereby the electric field accumulation between the gate electrode 25 and the first offset diffusion layer 32 may be relaxed by optimizing the conditions of the first offset diffusion layer 32 to make it possible to suppress the rise of the drain breakdown voltage at a channel end and to suppress the impact ionization phenomenon. Moreover, the electric field accumulation below the drain diffusion layer 34 may be relaxed by optimizing the conditions of the second offset diffusion layer 33, and thus, the structure has a high degree of flexibility in device designing in a desired high voltage range.

In the above, a case of an n-channel MOS transistor is described in detail, but it goes without saying that the present invention may also be applied to a case of a p-channel MOS transistor. When the MOS transistor is operated such that the source electrode and the drain electrode thereof are interchanged, the proper operation of both the source electrode and the drain electrode has to be ensured at a high voltage. Even in such a case, by applying the structure of the present invention to both the source diffusion layer and the drain diffusion layer, a high breakdown voltage may be ensured. Further, in the above, a case in which the MOS transistor is formed on a semiconductor substrate is described, but the present invention may also be applied to a case in which the MOS transistor is formed on a p-type deep diffusion layer, that is, a so-called well diffusion layer. Still further, the structure of the drain at a channel end is the same as that of a conventional LOCOS offset MOS transistor, and hence the characteristics of the MOS transistor are not inferior to those of the conventional MOS transistor.

What is claimed is:

1. A semiconductor device, comprising a MOS transistor comprising:
a gate electrode formed on a gate oxide film, the gate oxide film being formed on a surface of a semiconductor substrate of a first conductivity type;
a LOCOS oxide film and a first offset diffusion layer of a second conductivity type, which are formed on the surface of the semiconductor substrate at one of both sides and only one side of the gate electrode, a part of a region of the LOCOS oxide film, which is not an end of the LOCOS oxide film, being removed; and
one of both of a source diffusion layer and a drain diffusion layer of the second conductivity type and only a drain diffusion layer of the second conductivity type is formed in the first offset diffusion layer corresponding to the region in which the LOCOS oxide film is removed.

2. A semiconductor device according to claim 1, wherein the MOS transistor further comprises a second offset diffusion layer of the second conductivity type on a periphery of one of both of the source diffusion layer and the drain diffusion layer and only the drain diffusion layer.

3. A semiconductor device, comprising:
a semiconductor substrate of a first conductivity type;
a gate oxide film disposed on a surface of the semiconductor substrate and a LOCOS oxide film formed so as to be continuous with the gate oxide film;
a gate electrode continuously disposed between a surface of the gate oxide film and a surface of the LOCOS oxide film;
a first offset diffusion layer of a second conductivity type disposed on one end side of the gate electrode in a vicinity of the surface of the semiconductor substrate and below the LOCOS oxide film;
a drain region disposed in a region, in which a part of the LOCOS oxide film is etched to be removed and which also corresponds to a part of the first offset diffusion, so as to be shallower than the first offset diffusion layer; and
a source region of the second conductivity type disposed on another end side of the gate electrode.

4. A semiconductor device according to claim 3, further comprising a second offset diffusion layer of the second conductivity type disposed in a region inside the first offset diffusion layer in plan view so as to be larger and deeper than the drain region and has an impurity concentration which is higher than an impurity concentration of the first offset diffusion layer.

5. A method of manufacturing a semiconductor device, comprising:
forming a sacrificial oxide film on a semiconductor substrate of a first conductivity type;
forming a nitride film on the sacrificial oxide film;
etching the nitride film only in a desired region using a patterned photoresist;
forming by ion implantation an offset diffusion layer of a second conductivity type only in a region to be a first offset diffusion layer;
forming a LOCOS oxide film in the region in which the nitride film is etched;
removing the nitride film and the sacrificial oxide film;
forming a gate oxide film on a surface of the semiconductor substrate, forming a polycrystalline silicon film, and etching the polycrystalline silicon film only in a desired region using a patterned photoresist;
etching the LOCOS oxide film in a region of the LOCOS oxide film, in which one of both of a source diffusion layer and a drain diffusion layer and only a drain diffusion layer is to be formed, using a patterned photoresist; and
forming by ion implantation a source diffusion layer of the second conductivity type and a drain diffusion layer of the second conductivity type in one of only the region in which the LOCOS oxide film is removed and both the region in which the LOCOS oxide film is removed and the region in which the source diffusion layer is to be formed.

6. A method of manufacturing a semiconductor device, comprising:
forming a sacrificial oxide film on a semiconductor substrate of a first conductivity type;
forming a nitride film on the sacrificial oxide film;
etching the nitride film only in a desired region using a patterned photoresist;
forming by ion implantation a first offset diffusion layer of a second conductivity type only in a region to be the first offset diffusion layer;
forming by ion implantation a second offset diffusion layer of the second conductivity type only in a region to be the second offset diffusion layer;
forming a LOCOS oxide film in the region in which the nitride film is etched;
removing the nitride film and the sacrificial oxide film;
forming a gate oxide film on a surface of the semiconductor substrate, forming a polycrystalline silicon film, and etching the polycrystalline silicon film only in a desired region using a patterned photoresist;
etching the LOCOS oxide film in a region of the LOCOS oxide film, in which one of both of a source diffusion layer and a drain diffusion layer and only a drain diffusion layer is to be formed, using a patterned photoresist; and
forming by ion implantation a source diffusion layer of the second conductivity type and a drain diffusion layer of the second conductivity type in one of only the region in which the LOCOS oxide film is removed and both the region in which the LOCOS oxide film is removed and the region in which the source diffusion layer is to be formed.
